(19) United States
(12) Patent Application Publication
(10) Pub. No.: US 2024/0206045 A1
(43) Pub. Date: Jun. 20, 2024

(54) MAGNETIC MEANS FOR COATING SURFACES WITH LIQUIDS

(71) Applicant: Michael T. Kotschenruether, Austin, TX (US)

(72) Inventor: Michael T. Kotschenruether, Austin, TX (US)

(73) Assignee: Fusion Energy Associates LLC, Austin, TX (US)

(21) Appl. No.: 18/513,629

(22) Filed: Nov. 19, 2023

Related U.S. Application Data
(60) Provisional application No. 63/426,732, filed on Nov. 19, 2022.

(51) Int. Cl. H05H 1/10; C23C 14/24; C23C 14/34

(52) U.S. Cl. CPC H05H 1/10; C23C 14/24; C23C 14/34

(57) ABSTRACT

A plasma chamber surface including a solid surface with a liquid covering one side; regions on the surface with a gradient of the magnetic field such that the magnetic field strength increases going into the solid surface from the liquid; magnetic aspects present near the surface on the side opposite to the liquid for creating or modifying magnetic fields generated by at least one of ferromagnetic materials, paramagnetic materials, permanently magnetized materials, and electromagnets; wherein the liquid contains magnetic material that causes the liquid to be attracted to regions of higher magnetic field strength, and wherein the magnetic material comprises at least one of paramagnetic chemical elements, paramagnetic chemical compounds, ferromagnetic chemical elements, ferromagnetic chemical compounds, ferrimagnetic materials, superparamagnetic materials, and nanoparticles; and wherein the liquid is attracted to the surface and substantially continually covers a substantial portion of the surface.

### CROSS-REFERENCE TO RELATED APPLICATIONS

This application claims priority to U.S. provisional application Ser. No. 63/426,732, filed on Nov. 19, 2022, which is incorporated herein by reference in its entirety.

### FIELD OF INVENTION

This is related to the area of coating a large area of a solid surface by a liquid and maintaining the liquid in place by magnetic forces.

### BACKGROUND OF THE INVENTION

There are many circumstances where it is desirable to coat the large surface of a material with a thin liquid. In some cases, it is desirable for the coating to be a liquid and to remain a liquid for as long as it coats the surface. Circumstances where this is so include, but are not limited to, situations where erosion, corrosion, some chemical reaction or physical effect occurs at a surface, and it is desirable to coat it with a liquid that can be continuously replenished. The liquid should stay in place reliably on the solid surface without substantially leaving it by dripping, splashing, or spraying, even if forces of gravity or other forces would tend to cause the liquid to leave the surface. In some cases, such circumstances arise in an environment where there is already a substantial magnetic field, or, where it is a feasible way to apply such a magnetic field. One particular example of the former situation includes, but is not limited to, devices which have a plasma in close proximity to the wall. Examples of such devices include, but are not limited to, tokamaks, Spherical Tokamaks (STs), stellarators, magnetic mirrors, toroidal pinches, spheromaks, Reversed Field Pinches (RFPs) and Field Reversed Configurations (FRC). In some embodiments, these devices can be used to produce fusion energy. For devices that contain a plasma, substantial erosion can be caused by the effect of the plasma on material surfaces facing the plasma. Accordingly, improvements are sought in mitigating erosion of materials facing the plasma.

### SUMMARY OF THE INVENTION

It would be very advantageous to be able to coat material surfaces facing the plasma with a liquid, and to replenish that liquid, and thereby protect the solid material wall from erosion that would shorten the lifetime of the device. This would be advantageous as long as it was possible to prevent the liquid from dripping or splashing into the plasma and contaminating it, or otherwise moving to an undesirable location. There are other circumstances where it would be advantageous to coat a solid surface of significant area with a liquid and keep it in place on the solid surface. Henceforth, for simplicity we will refer to such a solid surface as a “wall”. Here is disclosed a method to coat a wall with a liquid and keep it in place magnetically.

A plasma chamber surface including a solid surface with a liquid covering one side; regions on the surface with a gradient of the magnetic field such that the magnetic field strength increases going into the solid surface from the liquid; magnetic aspects present near the surface on the side opposite to the liquid for creating or modifying magnetic fields generated by at least one of ferromagnetic materials, paramagnetic materials, permanently magnetized materials, and electromagnets; wherein the liquid contains magnetic material that causes the liquid to be attracted to regions of higher magnetic field strength, and wherein the magnetic material comprises at least one of paramagnetic chemical elements, paramagnetic chemical compounds, ferromagnetic chemical elements, ferromagnetic chemical compounds, ferrimagnetic materials, superparamagnetic materials, and nanoparticles; and wherein the liquid is attracted to the surface and substantially continually covers a substantial portion of the surface.

The disclosed systems and methods rely upon the presence of a magnetic field at the wall. That magnetic field can be externally generated, or it might be generated at the wall itself, or it could arise by some combination of these. The liquid that coats the wall has significant paramagnetism or ferromagnetism or other magnetic properties that cause it to be attracted to regions of higher magnetic field. We will use the term magnetic materials to refer to materials that experience a force in the presence of a magnetic field magnetic gradient that pushes toward higher field strength. The most common examples of these materials are paramagnetic or ferromagnetic materials, but any other material with this property could be used in this invention. The liquid is a magnetic material either because the dominant material of the liquid is itself such a material, or because materials are added to the liquid that are magnetic materials, or, by some combination of these.

To reiterate, the force upon a paramagnetic or ferromagnetic liquid is proportional to the magnetic field gradient, not the magnetic field itself. Of course, if there is an external magnetic field, one could rely upon gradients in the external magnetic field to exert force on the liquid. Denote the approximate magnitude of the field by ˜B₀. Because the surface has a large area, with a dimension ˜L that is large, and the magnetic field is generated externally over this region, the gradients are of order ˜B₀/L. Because L is rather large, this gradient is small, and so the magnetic forces are small. If the thickness of the liquid is thin, one only needs to have magnetic gradients in the small region of the liquid. Denote the approximate depth of the liquid by d. Because this distance is small, the gradients over the scale of the depth can potentially be much larger than gradients over the much longer scale of the external magnetic field. In other words, if the magnetic field ˜B₀ could be made to vary over a distance ˜d, the gradient would be ˜B₀/d, and this can be far larger than ˜B₀/L, since d is much less than L. To accomplish this requires a novel arrangement of means on the surface to modify the magnetic field.

The invention relates to means by which the magnetic force can be increased, by causing changes in the magnetic field strength over the thin region near the liquid. The invention relates to increasing the gradient of the magnetic field by creating multiple small-scale structures that modify the magnetic field. Because of their small scale, the distance over which the magnetic field is modified is also small. Hence the gradients of the magnetic field are much larger than the gradients of the externally generated field, and so the forces on the liquid made of magnetic material are increased. Furthermore, this can be done using an arrangement that allows the liquid to flow and be replenished.

There are multiple embodiments of this invention, with various different spatial structures. In some embodiments, the surface is not smooth, but has grooves, channels, indentations, dimples, or cavities. For simplicity we will henceforth refer to all of these as grooves. In one such embodiment, the wall is made of ferromagnetic material. In some embodiments, this could be ferritic steel, which is often used as a structural material. With reference to FIG. 1, the liquid 101 is on such a wall 102 that has groves. In this example, there is a magnetic field generated by external means that is substantially constant in space far from the surface. An exemplary magnetic field direction of the externally generated field 150 is shown in FIG. 1. The orientation shown is just one of many possibilities. The grooves have a bottom which has some depth into the wall. Because of the ferromagnetic material in the wall, the magnetic field is substantially stronger at the bottom of the groove than at the top. The distance over which the magnetic field varies has roughly the spatial scale of the grooves. The advantage of having grooves in the way just described is that it increases the gradient in the magnetic field strength in the region of the liquid. Hence, the liquid is attracted to the bottom of the groove more strongly than would be the case otherwise, and this is obviously beneficial in keeping the liquid on the surface.

### BRIEF DESCRIPTION OF THE DRAWINGS

FIG. 1 illustrates a cross-sectional side view of a wall surface having grooves such that the surface liquid can flow easily along the grooves, and thus can be replenished.

FIG. 2 illustrates a cross-sectional side view of a wall surface having grooves in a non-magnetic material with liquid on the surface, and with magnetic material located in some locations in the vicinity of the grooves.

FIG. 3 illustrates a cross-sectional side view of a wall surface without grooves in a non-magnetic material with liquid on the surface, and with magnetic material located in some locations in the vicinity of the grooves.

### DETAILED DESCRIPTION

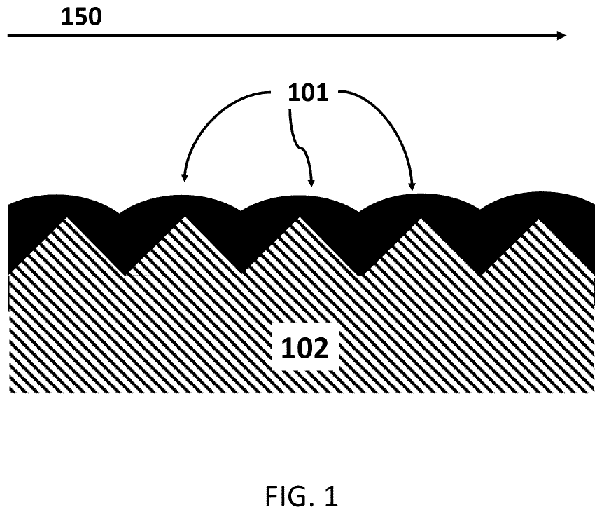

First, let us describe the nature of the wall material. As in FIG. 1, in one embodiment, the wall can be made of ferromagnetic material. Such materials include alloys that contain one or more elements including, but not limited to, iron, cobalt, nickel, or rare earth elements, as it already known in the art. In some embodiments, the wall can be made of a type of steel that is ferromagnetic, and such steels are often used as structural materials. This is also a common choice of structural material in proposed fusion reactors.

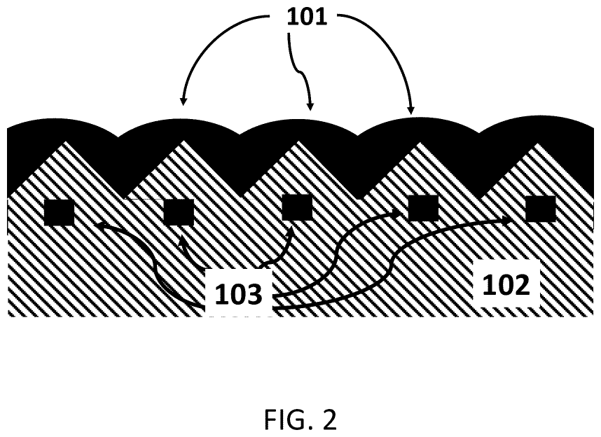

Or in another embodiment, as in FIG. 2 the wall can still have grooves. but consist primarily of non-ferromagnetic material. However, magnetic material of various kinds can be added to it. Such magnetic materials include alloys that contain one or more elements including, but not limited to, iron, cobalt, nickel, or rare earth elements, as it already known in the art. In yet other embodiments, the wall can contain permanent magnetic materials or wires with current to generate magnetic field.

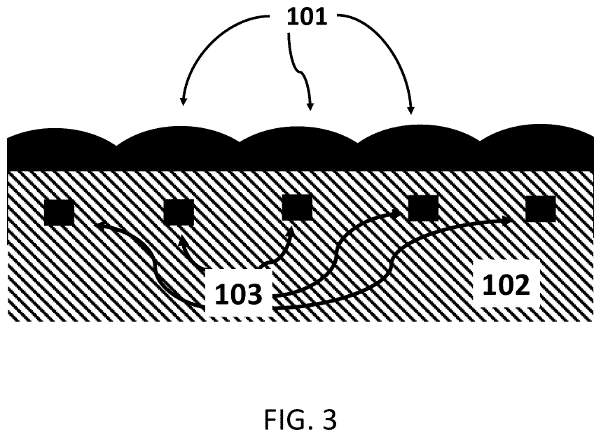

Or in another embodiment, as in FIG. 3, there are no grooves, but there is still magnetic material 103 distributed behind the wall. Such magnetic materials include alloys that contain one or more elements including, but not limited to, iron, cobalt, nickel, or rare earth elements, as it already known in the art. In yet other embodiments, the wall can contain permanent magnetic materials or wires with current to generate magnetic field.

In some embodiments there is a magnetic field generated by means away from the wall. In this case material 103 might be a ferritic steel, which is a common choice of structural material in many situations, including in fusion reactors that contain a plasma. It might also be any of a large variety of ferromagnetic materials known in the art, or paramagnetic materials, including, but not limited to, those containing Fe, Ni, Co, or rare earth elements including, but not limited to, Nd, Gd or rare earths elements (where the standard chemical symbol of an element has been used). In other embodiments, material 103 may be a permanent magnet. In yet other embodiments material 103 might be an electromagnet where current flows help to generate the magnetic field.

Note that in the case where material 103 is a permanent magnet or an electromagnet, an external magnetic field is not needed. However, there can still be benefits to having such a magnetic field, as will be clear in a detailed description of the invention. These are just exemplary embodiments of multiple small-scale structures in the vicinity of the wall that create magnetic forces that press the liquid to the wall.

In some embodiments, the scale size of the structures in FIG. 1, FIG. 2 and FIG. 3 is on the order of millimeters. In other embodiments, the scale size of the structures is smaller than of order millimeters. In yet other embodiments, the scale size of the structures is on the order of centimeters. In all these cases, surface tension is helpful in keeping the liquid in place. Surface tension is more helpful the smaller the scale size.

Let us give several possible benefits of adding small scale structures to the wall to modify the magnetic field and thus increase the attractive force of the liquid to the wall. This is obviously beneficial to maintaining the liquid on the wall in the presence of other forces that would tend to separate it from the wall, including but not limited to gravity or inertial forces. For example, FIG. 1 could be rotated 180 degrees so that gravity would tend to pull the liquid from the wall. The magnetic forces would counteract this, allowing the liquid to coat surfaces “on the ceiling” so to speak. There are many circumstances where forces could tend to separate the liquid from the wall. In some embodiments, inertial forces from liquid motion or turbulence could tend to cause such separation. In yet other embodiments, conditions outside of the wall could lead to electromagnetic fluctuations at the wall that cause forces in the liquid to try to separate it. In yet other embodiments, some other force could arise. But the magnetic forces, if they are strong enough, overcome these to keep the liquid on the wall.

Several other benefits arise from adding small-scale structures to increase the magnetic field gradient: 1) it is possible to use a lower magnetic field, and since stronger magnetic fields are usually more expensive, this is obviously a benefit, 2) the stronger force allows one to use a liquid with a lower amount of magnetic property, so that a wider class of liquids can be used, or, 3) a smaller amount of paramagnetic material or ferromagnetic material must be added to the liquid to cause sufficient attraction. Reducing the amount of paramagnetic material is an advantage because ferromagnetic or paramagnetic materials can be expensive or rare (i.e., rare earth elements or nanoparticles) or have limited solubility in the liquid, so that only a limited amount of magnetic material can be present in the liquid. So, because the small-scale structures increase the magnetic field gradient, and hence the attractive force, it becomes possible to have sufficient attractive magnetic force to overcome other forces, including but not limited to gravity, even though the liquid has a limited amount of magnetic material in it.

Note that the presence of an externally generated magnetic field can synergistically increase the magnetic field gradient, even if the external field has negligible gradient. The magnetic force is usually proportional to gradients of the total field strength B, or for linear media, the gradient of the total field strength B squared. Let us consider the combined effect of an external field together with magnetic field variations from small scale structures. Suppose that magnetic structures near the wall produce a magnetic field

$$\begin{matrix}Δ \vec{B}\end{matrix} .$$

Suppose that there is also an externally generated field

$$\text{} \begin{matrix}\vec{{B}_{0}}\end{matrix} \text{}$$

with negligible gradient. Then the square of the magnitude of the total field

$$\text{} \begin{matrix}\vec{B}\end{matrix} \text{} = \text{} \begin{matrix}\vec{{B}_{0}} + Δ \vec{B}\end{matrix} \text{}$$

is, by standard vector arithmetic, magnitude of the total field

$$\vert \begin{matrix}{\vec{β} \vert}^{2}\end{matrix} \text{} = \text{} \begin{matrix}{\vert \vec{{B}_{0}} + Δ \vec{B} \vert}^{2}\end{matrix} \text{} = \text{} \begin{matrix}{\vert \vec{{B}_{0}} \vert}^{2} + 2 \vec{{B}_{0}} \cdot Δ \vec{B} + {\vert Δ \vec{B} \vert}^{2}\end{matrix} \text{}$$

Forces are proportional to gradients of this. The gradient vanishes for the first term on the RHS which is due to the external field

$$\text{} \begin{matrix}\vec{{B}_{0}}\end{matrix} \text{}$$

alone. The

$$Δ \vec{B}$$

has short spatial scale, so both the second and the third term on the right have this scale and have gradients. But the size of second term will exceed the third if

$$\text{} \begin{matrix}\vec{{B}_{0}}\end{matrix} \text{}$$

is much larger than

$$\begin{matrix}Δ \vec{B}\end{matrix} .$$

So, the external field

$$\text{} \begin{matrix}\vec{{B}_{0}}\end{matrix} \text{}$$

increases the gradient that arises from

$$\begin{matrix}Δ \vec{B}\end{matrix} .$$

Even though

$$\text{} \begin{matrix}\vec{{B}_{0}}\end{matrix} \text{}$$

has no gradient, and so gives no magnetic force on its own, it can lead to a stronger gradient (and thus force) than would arise from

$$Δ \vec{B}$$

alone.

This could be considered a surprising synergistic effect, and it is an inevitable consequence of vector arithmetic, together with the fact that force on magnetic materials is proportional to the gradient of the magnetic field strength.

In some embodiments, the magnetic liquid is a molten metal which is itself paramagnetic or ferromagnetic or otherwise is a magnetic material. Examples of the former include, but are not limited to, molten lithium, aluminum, or bismuth. Examples of magnetic material that can be added to the liquid include, but are not limited to, manganese, iron, cobalt, nickel, or a rare earth element such as cerium, praseodymium, neodymium, samarium, europium, gadolinium, terbium, dysprosium, holmium, or erbium. Or, in some other embodiments, the liquid might be a molten salt, and the liquid can contain some paramagnetic or ferromagnetic element including, but not limited to, manganese, iron, cobalt, nickel, or a rare earth element in the form of come compound or element. Or, in yet other embodiments, the liquid could be water or some solvent with paramagnetic salts added to it. Or in yet other embodiments, the liquid could contain a colloidal suspension of magnetic materials. In yet other embodiments, the liquid could have nanoparticles added to it, and nanoparticles might possess superparamagnetism, or otherwise be magnetic materials.

These methods are used for imbuing a liquid with a magnetic force toward a stronger magnetic field when in the presence of a magnetic field gradient.

In some embodiments, the grooves extend lengthwise, like channels, to allow the liquid to flow inside them, so that the liquid can continuously or periodically be replenished by this flow.

The liquid can contain material in addition to paramagnetic material that makes it more advantageous to the environment of the liquid. In one embodiment, the region facing the liquid may have material where chemical or nuclear reactions are happening, and the liquid may contain materials in addition to magnetic materials, to affect those reactions in some advantageous way, or to prevent a deleterious effect upon the reactions. In one embodiment, the region facing the liquid and the wall may contain a plasma that is impinging upon the liquid. Magnetic forces keep the liquid on the wall, and other materials are present in the liquid so that the materials sputtering or evaporated from the liquid has a desirable effect upon the plasma. In the case of plasmas used to create fusion energy, the materials can be chosen to cause less degradation to it, by being of low atomic number Z, including, but not limited to, Li, Be, Mg, Al, Si, Ca, O, N, F, C, P, S, Cl, or H, or compounds thereof. In yet other embodiments, the material evaporated or sputtered into the plasma may impart some other desirable property to the plasma.

Also, in some embodiments, the interface between the paramagnetic liquid and the wall can itself be coated with another solid material to reduce corrosion of the wall by the liquid itself, or to engender more favorable interactions between the wall and the liquid. Such a solid coating is not held in place by magnetic forces, but by adhesion of the solid coating to the wall. As one possible example of this, the wall can be coated with a refractory metal to reduce corrosion.

Or, in yet other embodiments, if the liquid is a conducting material, the wall can be coated with a solid metal to give a Seebeck effect with the liquid, so that currents are induced in the liquid. This leads to Lorentz forces with the magnetic field, to cause the liquid to flow along the grooves. The use of the Seebeck effect in liquid metals in a magnetic field in order to propel a liquid into motion in grooves is already known in the art [Ruzic 2011]. The present invention could be used in conjunction with such means as well, where magnetic forces are used to keep the liquid firmly on the wall, while the Seebeck effect propels the liquid along the grooves.

Finally, while the present invention has been described above with reference to various exemplary embodiments, many changes, combinations and modifications may be made to the exemplary embodiments without departing from the scope of the present invention. For example, the various components may be implemented in alternative ways. These alternatives can be suitably selected depending upon the particular application or in consideration of any number of factors associated with the operation of the device. In addition, the techniques described herein may be extended or modified for use with other types of devices. These and other changes or modifications are intended to be included within the scope of the present invention.

What is claimed is:

1. A plasma chamber surface comprising:
a surface of a solid which has a liquid covering one side;
regions on the surface where there is a gradient of the magnetic field such that the magnetic field strength increases going into the solid surface from the liquid;
one or more magnetic aspects present near the surface on the side opposite to the liquid, said aspects creating or modifying magnetic fields generated by at least one of ferromagnetic materials, paramagnetic materials, permanently magnetized materials, and electromagnets;
wherein the liquid contains magnetic material that causes the liquid to be attracted to regions of higher magnetic field strength, and wherein the magnetic material comprises at least one of paramagnetic chemical elements, paramagnetic chemical compounds, ferromagnetic chemical elements, ferromagnetic chemical compounds, ferrimagnetic materials, superparamagnetic materials, and nanoparticles; and
wherein the liquid is attracted to the surface and substantially continually covers a substantial portion of the surface.

2. The plasma chamber surface of claim 1, wherein sections of the liquid surface are exposed to at least one of a plasma and high-energy particles striking the liquid surface.

3. The plasma chamber surface of claim 1, wherein the solid surface defines at least one of grooves, channels, indentations, dimples, and cavities.

4. The plasma chamber surface of claim 3, wherein the material of the solid surface defining the least one of grooves, channels, indentations, dimples, and cavities comprises a magnetic material that is at least one of ferromagnetic, paramagnetic, and permanently magnetized, and wherein the at least one of grooves, channels, indentations, dimples, and cavities comprise magnetic elements that contribute to the gradient of the magnetic field into the surface.

5. The plasma chamber surface of claim 1, wherein a magnetic field is generated by means external to the region near the surface.

6. The plasma chamber surface of claim 2, wherein a magnetic field is generated by means external to the region near the surface.

7. The plasma chamber surface of claim 3, wherein a magnetic field is generated by means external to the region near the surface.

8. The plasma chamber surface of claim 3, wherein sections of the liquid surface are exposed to at least one of a plasma and high-energy particles striking the liquid surface.

9. The plasma chamber surface of claim 4, wherein sections of the liquid surface are exposed to at least one of a plasma and high-energy particles striking the liquid surface.

10. The plasma chamber surface of claim 5, wherein sections of the liquid surface are exposed to at least one of a plasma and high-energy particles striking the liquid surface.

11. The plasma chamber surface of claim 6, wherein sections of the liquid surface are exposed to at least one of a plasma and high-energy particles striking the liquid surface.

12. The plasma chamber surface of claim 7, wherein sections of the liquid surface are exposed to at least one of a plasma and high-energy particles striking the liquid surface.

13. The plasma chamber surface of claim 3, wherein the liquid is a conductor and currents flow through the conductor causing forces together with the magnetic field to propel the liquid into motion through the at least one of grooves, channels, indentations, dimples, and cavities.

14. The plasma chamber surface of claim 13, wherein sections of the liquid surface are exposed to at least one of a plasma and high-energy particles striking the liquid surface.

15. The plasma chamber surface of claim 2, configured within a device to magnetically confine plasma, the device comprising at least one of a tokamak, spherical tokamak, stellarator, toroidal pinch, Reversed Field Pinch, Field Reversed Configuration, mirror, tandem mirror, and Z-pinch.

16. The plasma chamber surface of claim 3, configured within a device to magnetically confine plasma, the device comprising at least one of a tokamak, spherical tokamak, stellarator, toroidal pinch, Reversed Field Pinch, Field Reversed Configuration, mirror, tandem mirror, and Z-pinch.

17. The plasma chamber surface of claim 13, configured within a device to magnetically confine plasma, the device comprising at least one of a tokamak, spherical tokamak, stellarator, toroidal pinch, Reversed Field Pinch, Field Reversed Configuration, mirror, tandem mirror, and Z-pinch.
